(19) United States
(12) Patent Application Publication
(10) Pub. No.: US 2010/0071948 A1
(43) Pub. Date: Mar. 25, 2010

(54) PRINTED CIRCUIT BOARD AND METHOD OF MANUFACTURING THE SAME

(75) Inventor: YI-KUANG WEI, Taipei Hsien (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Taipei Hsien (TW)

(21) Appl. No.: 12/250,497

(22) Filed: Oct. 13, 2008

(30) Foreign Application Priority Data
Sep. 19, 2008 (CN) 200810304587.X

(51) Int. Cl. H05K 1/11; H05K 3/00

(52) U.S. Cl. 174/261; 29/829

(57) ABSTRACT

A printed circuit board includes a signal layer, an insulation layer, and a reference layer. A transmission line is located on the signal layer. A test point is located on the transmission line. A hole is defined in the reference layer and under the test point. The signal layer, the insulation layer, and the reference layer are configured in a cascading order. Wherein an arrangement of the signal layer in relation to the reference layer comprising the hole reduces a capacitance effect caused by the test point. A method of manufacturing the printed circuit board is provided.

### BACKGROUND

1. Field of the Disclosure

The present disclosure relates to a printed circuit board (PCB) and a method of manufacturing the same.

2. Description of the Related Art

When an important transmission line of a PCB is in a ball grid array (BGA) or other limited space package, it is hard to access for debugging purposes. A designer will often opt to add a test point on the transmission line to make debugging easier. The test point is used for testing a signal of the transmission line easily with a probe. However, adding a test point is equal to adding a capacitor in the transmission line, which may effect signal quality.

### BRIEF DESCRIPTION OF THE DRAWINGS

FIG. 1 is an isometric, exploded view of an exemplary embodiment of a printed circuit board including a first signal layer, a first prepreg, and a power layer.

FIG. 2 is a top plan view of the first signal layer of FIG. 1.

FIG. 3 is an exploded, isometric view of the first signal layer, the first prepreg, and the power layer of FIG. 1, the first signal layer includes a test point, the power layer defines a hole.

FIG. 4 is a signal attenuation graph at different radiuses of the hole of FIG. 3.

FIG. 5 is a signal attenuation graph when the frequency of the signal is 10 Ghz at different radiuses of the hole of FIG. 3.

### DETAILED DESCRIPTION

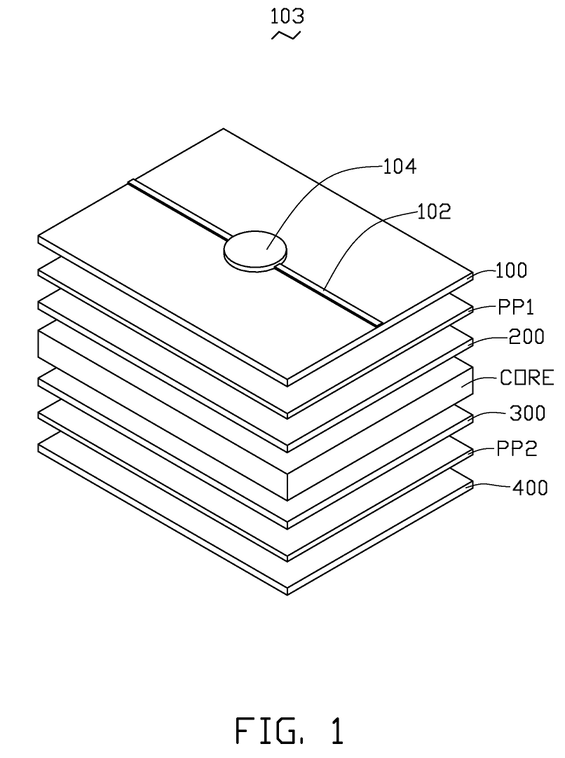

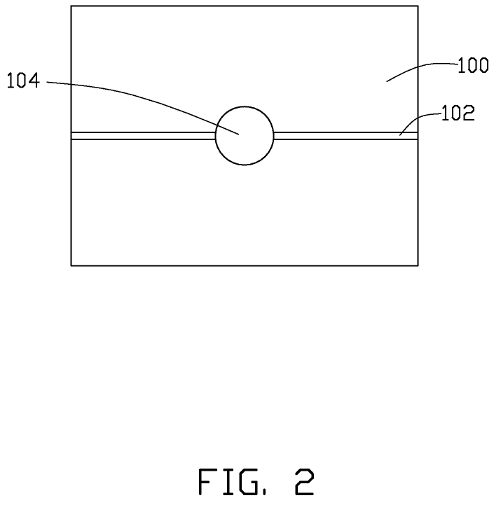

Referring to FIG. 1 and FIG. 2, an exemplary embodiment of a printed circuit board (PCB) 103 includes a first signal layer 100, a power layer 200, a ground layer 300, and a second signal layer 400. The first signal layer 100 is mounted on a first prepreg PP1, and configured for signal transmission. It may be understood that the term “prepreg” defines a “pre-impregnated” composite fiber layer. Further details of the layer will be explained in further detail below. The power layer 200 is mounted under the first prepreg PP1, and configured for supplying power for the first signal layer 100 and the second signal layer 400. The first prepreg PP1, functioning as a first insulation layer, is configured for insulating the first signal layer 100 from the power layer 200. The ground layer 300 is mounted on a second prepreg PP2, and configured for grounding the first signal layer 100 and the second signal layer 400. The second signal layer 400 is mounted under the second prepreg PP2, and configured for signal transmission. The second prepreg PP2, functioning as a second insulation layer, is configured for insulating the ground layer 300 from the second signal layer 400. The power layer 200 functions as a reference layer of the first signal layer 100. The ground layer 200 functions as a reference layer of the second signal layer 400. The power layer 200 and the ground layer 300 are agglutinated to and insulated with a core board CORE. The first signal layer 100, the power layer 200, the ground layer 300, and the second signal layer 400 are configured in a cascading order.

The first prepreg PP1 and the second prepreg PP2 are made of insulation carrier materials, such as glass fiber mats which have been impregnated with epoxy resin. The first prepreg PP1, the second prepreg PP2, and the core board CORE are capable of insulating the first signal layer 100, the power layer 200, the ground layer 300, and the second signal layer 400. A transmission line 102 is located on the first signal layer 100, and configured for transmitting a signal. A test point 104 is located on the transmission line 102. Surfaces of the first signal layer 100 and the second signal layer 400 are covered with solder mask (not shown) to protect or mask certain areas of the PCB 103. Since the solder mask covers most of the surface of the PCB 103, the solder mask can protect circuits of the PCB 103 and provide electrical insulation. It may be understood that the transmission line 102 is covered with the solder mask, but the test point 104 is not.

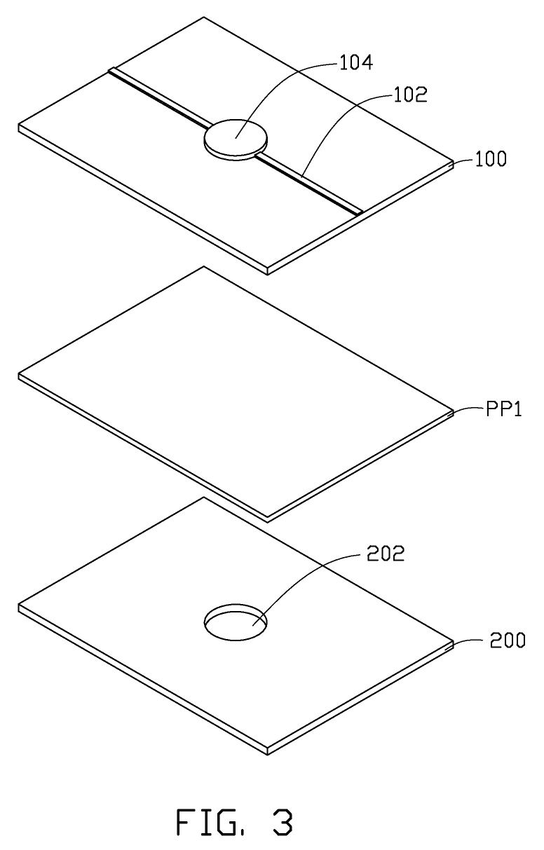

Referring to FIG. 3, a hole 202 is defined in the power layer 200 under the test point 104. The hole 202 is formed by etching a copper foil of the power layer 200, which reduces a capacitance effect caused by the test point 104.

In one exemplary embodiment, parameters of the PCB 103 are as follows: a thicknesses the first signal layer 100, the power layer 200, the ground layer 300, and the second signal layer 400 are all about T1=1.2 mil; thickness of the solder mask on each of the first signal layer 100 and the second signal layer 400 is about T2=0.7 mil; thickness of the solder mask on the transmission line is about T3=0.5 mil; thickness of each of the first prepreg PP1 and the second prepreg PP2 is about T4=2.6 mil; dielectric constant of each of the first prepreg PP1 and the second prepreg PP2 is about Dk1=3.7; dissipation factor of each of the first prepreg PP1 and the second prepreg PP2 is about Df1=0.02; thickness of the core board CORE is about T5=47 mil; radius of the test point 104 is about r1=15 mil; dielectric constant of the test point 104 is about Dk2=4.0; dissipation factor of the test point 104 is about Df2=0.02; thickness of the transmission line 102 is about T6=1.6 mil; length of the transmission line 102 is about L1=400 mil. The PCB 103 can be simulated in a simulation system according to the above-mentioned parameters in order to determine an optimum radius HR of the hole 202.

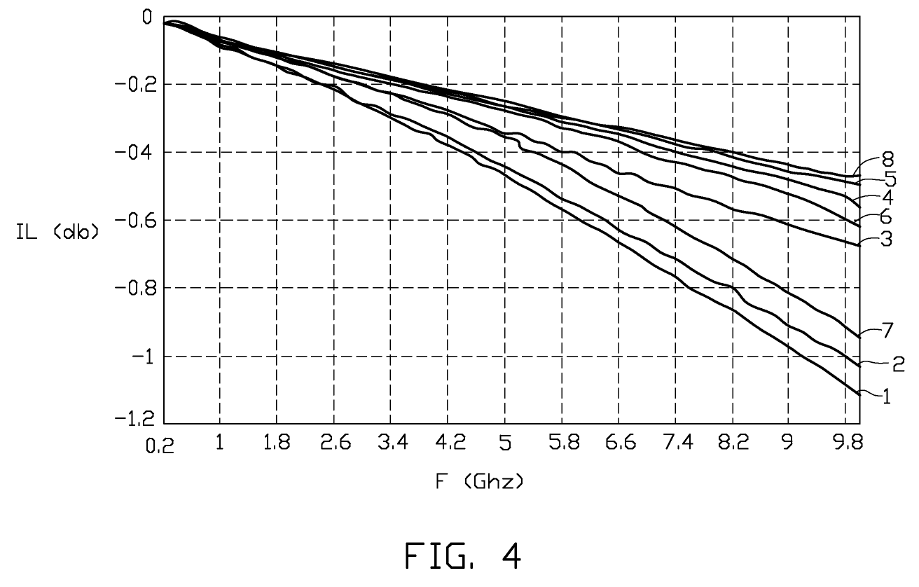

FIG. 4 is an attenuation graph of a signal transmitted by the transmission line 102 using different values for the radius HR of the hole 202. The abscissa of FIG. 4 is a frequency F of the signal, and the ordinate is an insertion loss IL of the signal. As shown, when the IL=−0.2 db, the insertion loss of the signal is 0.2 db. In FIG. 4, the curve 1 shows signal attenuation when the PCB 103 does not include the hole 202 but includes the test point 104. The curve 8 shows signal attenuation when the PCB 103 does not include the test point 104 or the hole 202. The curves 2-7 show signal attenuation when the PCB 103 includes the test point 104 and the hole 202 with radius values for HR of the hole 202 of 6 mil, 12 mil, 15 mil, 16.5 mil, 18 mil, and 24 mil. It can be seen in FIG. 4 that, when the transmission line 102 transmits a high frequency signal, the insertion loss of the signal when the PCB103 includes the hole 202 and the test point 104, is lower than the insertion loss of the signal when the PCB 103 does not include the hole 202. The signal insertion loss of curve 5 is almost equal to the signal insertion loss of curve 8 when the signal frequency is about 10 Ghz. Therefore, the optimum radius HR of the hole 202 is about 16.5 mil when the radius r1 of the test point 104 is about 15 mil. Thereby the capacitance effect of the test point 104 can be reduced or eliminated.

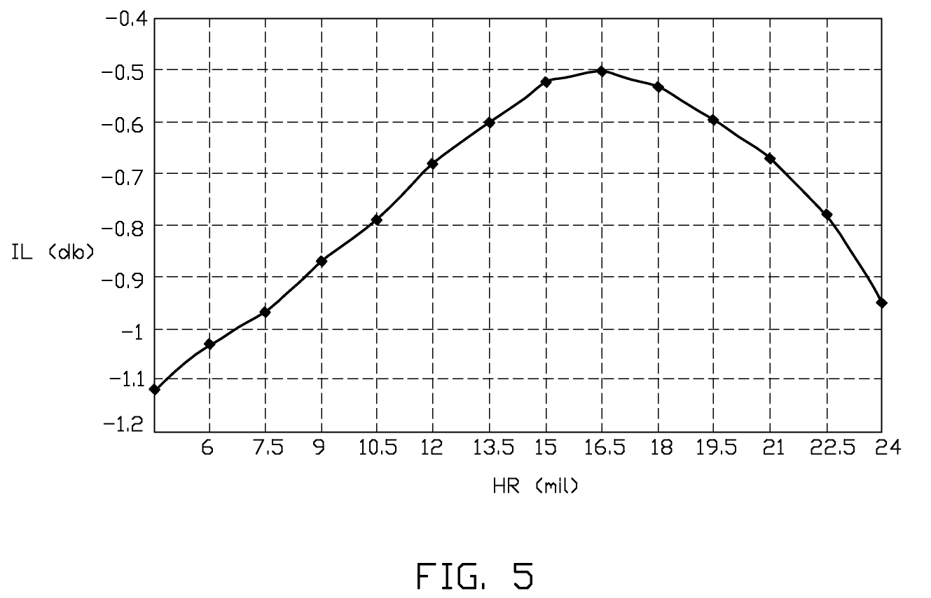

FIG. 5 is an attenuation graph of the signal transmitted by the transmission line 102 when the frequency of the signal is about 10 Ghz at different values of the radius HR of the hole 202. The abscissa of FIG. 5 is the radius HR of the hole 202, and the ordinate is the insertion loss IL of the signal. It also can be seen in FIG. 5 that the optimum radius HR of the hole 202 is about 16.5 mil when the radius r1 of the test point 104 is about 15 mil.

In other exemplary embodiments, the hole 202 can be defined in the ground layer 300 when the transmission line 102 and the test point 104 are located on the second signal layer 400. The hole 202 is over the test point 104 to reduce the capacitance effect. The PCB 103 can also be 2-layer or multi-layer. When the PCB 103 is 2-layer, the power layer 200 and the ground layer 300 are arranged at a same layer to function as a reference layer of the first signal layer 100. In summary, the hole 202 can be defined in a reference layer adjacent to a signal layer which has the test point 104, wherein an arrangement of the signal layer in relation to the reference layer comprising the hole 202 reduces or substantially eliminates the capacitance effect caused by the test point 104.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A printed circuit board, comprising:
a signal layer configured for signal transmission;
a reference layer adjacent to the signal layer;
an insulation layer capable of insulating the signal layer and the reference layer;
a transmission line located on the signal layer, and configured for transmitting a signal;
a test point located on the transmission line and configured for testing the signal in response to a contact with a probe; and
a hole defined in the reference layer and under the test point;
wherein the signal layer, the insulation layer, and the reference layer are configured in a cascading order; wherein an arrangement of the signal layer in relation to the reference layer comprising the hole reduces a capacitance effect caused by the test point.

2. The printed circuit board of claim 1, wherein the reference layer is a power layer.

3. The printed circuit board of claim 1, wherein the reference layer is a ground layer.

4. The printed circuit board of claim 1, wherein a radius of the test point is about 15 mil.

5. The printed circuit board of claim 1, wherein a radius of the hole is about 16.5 mil.

6. The printed circuit board of claim 1, wherein the hole is formed by etching a copper foil of the reference layer.

7. A method of manufacturing a printed circuit board, comprising:
mounting a test point on a transmission line on a signal layer, wherein the signal layer is configured for signal transmission, the transmission line capable of transmitting a signal, and the test point is configured for testing the signal in response to a contact with a probe;
defining a hole on a reference layer and under the test point, wherein the reference layer is adjacent to the signal layer; and
configuring the signal layer, an insulation layer, and the reference in a cascading order;
wherein an arrangement of the signal layer in relation to the reference layer comprising the hole reduces a capacitance effect caused by the test point.

8. The method of claim 7, wherein the reference layer is a power layer.

9. The method of claim 7, wherein the reference layer is a ground layer.

10. The method claim 7, wherein a radius of the test point is about 15 mil.

11. The method of claim 7, wherein a radius of the hole is about 16.5 mil.

12. The method of claim 7, wherein the hole is formed by etching a copper foil of the reference layer.
